(19) United States
(12) Patent Application Publication
(10) Pub. No.: US 2026/0304819 A1
(43) Pub. Date: Oct. 1, 2026

(54) STRAIN ENGINEERING IN TWO-DIMENSIONAL MATERIALS FOR HIGH-PERFORMANCE TRANSISTORS

(71) Applicant: Intel Corporation, Santa Clara, CA (US)

(72) Inventors: Mahmut Sami Kavrik, Portland, OR (US); Kevin P. O'Brien, Portland, OR (US); Uygar E. Avci, Portland, OR (US); Chia-Ching Lin, Portland, OR (US); Nazmul Arefin, Beaverton, OR (US)

(73) Assignee: Intel Corporation, Santa Clara, CA (US)

(21) Appl. No.: 19/094,553

(22) Filed: Mar. 28, 2025

(51) Int. Cl. H10D 30/47; H10D 30/01

(52) U.S. Cl. CPC H10D 30/481; H10D 30/017

(57) ABSTRACT

Devices and systems with strained two-dimensional (2D) materials, and methods of forming the same, are disclosed herein. In one example, a semiconductor device includes source and drain contacts, a channel extending between the source and drain contacts, and a gate over the channel. The source and drain contacts include one or more stressed metals, and the channel includes a strained 2D material.

### BACKGROUND

Conventional bulk silicon transistors are approaching their scalability limits, as reducing their dimensions further decreases carrier mobility and eventually leads to degraded performance. Due to these limitations, two-dimensional (2D) transistors have emerged as a promising alternative to continue scaling down the size of the next generation of transistors. In particular, 2D transistors use 2D materials with atomic-scale thickness as the semiconducting channel, and carrier mobility remains intact even in sub-nanometer-thin 2D layers, which means 2D transistors can be scaled down significantly without impacting performance. However, 2D materials are susceptible to various defects during fabrication, such as chalcogen deficiencies, which reduces carrier mobility in the 2D materials. As a result, 2D transistors may suffer from degraded performance due to these defects.

### BRIEF DESCRIPTION OF THE DRAWINGS

FIG. 1 illustrates an example of a 2D transistor with a strained channel induced by stressed source/drain contacts.

FIGS. 2A-D illustrate an example process flow for forming a 2D transistor with a strained channel induced by stressed source/drain contacts.

FIGS. 3A-D illustrate examples of strained 2D transistors with stressed source/drain contacts in varying configurations.

FIG. 4 illustrates another example of a strained 2D transistor with stressed source/drain contacts.

FIGS. 5A-H illustrate another example process flow for forming a strained 2D transistor with stressed source/drain contacts.

FIG. 6 illustrates an example of a 2D transistor with a strained channel induced by stressed insulators.

FIGS. 7A-D illustrate an example process flow for forming a 2D transistor with a strained channel induced by stressed insulators.

FIGS. 8A-B illustrate an example of a strained 2D gate-all-around (GAA) transistor with stressed source/drain contacts.

FIG. 9 illustrates a top view of a wafer and dies that may be included in a microelectronic assembly.

FIG. 10 illustrates a cross-sectional view of an integrated circuit device that may be included in a microelectronic assembly.

FIGS. 11A-D illustrate perspective views of example planar, FinFET, gate-all-around, and stacked gate-all-around transistors.

FIG. 12 illustrates a cross-sectional view of an integrated circuit device assembly that may include a microelectronic assembly.

FIG. 13 illustrates a block diagram of an example electrical device that may include a microelectronic assembly.

### DETAILED DESCRIPTION

As the latest generations of transistors continue to shrink in size, conventional bulk silicon transistors are approaching their scalability limits, as further reductions in their dimensions ultimately lead to degraded performance. In particular, as the thickness of the silicon channel is reduced (e.g., the channel becomes thinner), carrier mobility in the channel decreases, which reduces overall device performance.

Due to these limitations, two-dimensional (2D) transistors have emerged as a promising alternative to continue scaling down the next generation of transistors. 2D transistors are a class of transistors that use 2D materials as the semiconductor channel for electron or hole transport. 2D materials are ultrathin materials with atomic-scale thickness (e.g., typically ranging from one to a few atomic layers thick), such as transition metal dichalcogenides (TMDs) (e.g., MoS₂, WS₂), Group III-VI semiconductors (e.g., InSe), or oxide semiconductors (e.g., BiOSe). Compared to conventional bulk silicon-based transistors, 2D transistors offer several advantages, including high carrier mobility, enhanced electrostatic control, and reduced short-channel effects (SCEs) due to their atomically thin structure, larger effective electron/hole mass, and larger bandgap (e.g., which reduces band-to-band (BTB) tunneling). In particular, the atomic-scale thickness of 2D materials enables ultra-scaled transistors with a thinner body (e.g., channel), which enables denser stacking (e.g., leading to lower device capacitance) and increases robustness to short-channel effects. Moreover, carrier mobility remains intact even in sub-nanometer-thin 2D layers, which means 2D transistors can be scaled down significantly without impacting performance. These advantages make 2D transistors particularly attractive for next-generation semiconductor devices.

However, the integration of 2D materials into field-effect transistors (FETs) and ferroelectric FETs (FeFETs) comes with various challenges. In particular, 2D materials are susceptible to various defects, such as chalcogen deficiencies, which may arise from growth of the materials or other steps of device fabrication. Moreover, carrier mobility in 2D materials is highly sensitive to the density of these defects. As a result, 2D transistors may suffer from degraded performance due to low carrier mobility caused by defects in the 2D materials.

Accordingly, this disclosure presents embodiments of strained 2D transistors that are strain engineered to increase carrier mobility in the channel. Strain engineering is a technique used in semiconductor manufacturing to enhance device performance by applying mechanical stress (e.g., tensile or compressive stress) to a material to alter its atomic structure and intentionally modify its properties. This approach can be employed to enhance transistor performance by optimizing carrier mobility in the channel. For example, by modulating or inducing strain in the transistor channel, carrier mobility—whether electron or hole mobility—can be significantly increased, leading to improved conductivity and overall device efficiency, faster switching speeds, and lower power consumption.

In this disclosure, strain engineering is used to enhance the performance of 2D transistors by strategically inducing stress in the 2D material in the channel to increase carrier mobility. In some embodiments, for example, source/drain contacts and/or insulators are strategically engineered to induce stress in the 2D channel material, which strains the 2D material and increases carrier mobility.

The described embodiments may provide various advantages, including increasing carrier mobility in the 2D channel material via strain engineering, which boosts 2D transistor performance and enables the next generation of transistor scaling using 2D materials. Moreover, the strain-engineered increase in carrier mobility compensates for any reduction in carrier mobility from manufacturing defects in the 2D materials, which enables high-performance 2D FETs and FeFETs.

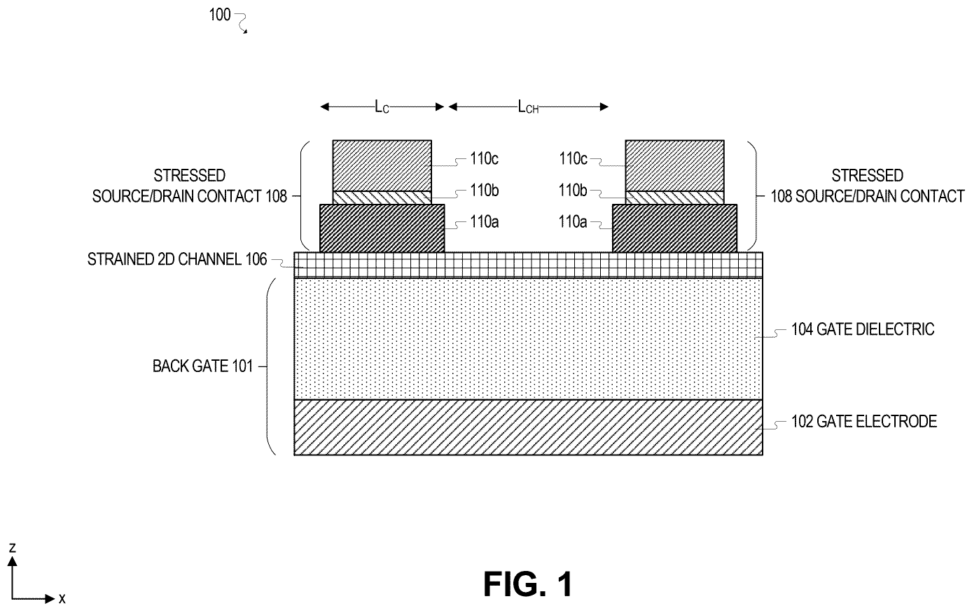

FIG. 1 illustrates a cross-section (x-z plane) view of a 2D transistor 100 with a strained channel 106 induced by stressed source/drain contacts 108. In particular, stress from the source/drain contacts 108 induces strain in the 2D channel 106, which increases carrier mobility in the channel 106, as described further below.

In the illustrated embodiment, transistor 100 is a back-gated strained 2D transistor, which includes a strained 2D channel 106, stressed source/drain contacts 108 over (e.g., above) opposite ends of the channel 106 on the frontside (e.g., such that the channel 106 extends between the source/drain contacts 108), and a back gate 101 over (e.g., below) the channel 106 on the backside.

The back gate 101 includes a gate electrode 102 and a gate dielectric 104 (e.g., with the gate dielectric 104 between the gate electrode 102 and the channel 106). In some embodiments, the gate electrode 102 may include heavily doped silicon, such as heavily p-doped silicon (p++Si) or heavily n-doped silicon (n++Si). In some embodiments, the heavily doped silicon gate electrode 102 may be a silicon substrate on which the transistor 100 is fabricated. Moreover, the gate dielectric 104 may include any suitable dielectric, such as silicon dioxide (e.g., SiO₂). In some embodiments, the gate dielectric 104 may additionally or alternatively include one or more dipole shifting layers (e.g., for threshold voltage (V_{T}) centering), such as magnesium oxide (e.g., MgO) for NMOS and tungsten oxide (e.g., WO₃) for PMOS.

In the illustrated embodiment, the gate 101 is a back gate, which is positioned on the backside of the channel 106 (e.g., the opposite side of the channel 106 as the source/drain contacts 108). In other embodiments, the gate 101 may be a front gate, which is positioned on the frontside of the channel 106 (e.g., the same side of the channel 106 as the source/drain contacts 108).

The 2D channel 106 includes one or more 2D materials, which are ultrathin materials with atomic-scale thickness (e.g., typically ranging from one to a few atomic layers thick). In some embodiments, for example, the 2D channel 106 may include one or more transition metal dichalcogenides (TMDs), such as molybdenum disulfide (MoS₂) or tungsten disulfide (WS₂). Alternatively, or additionally, the 2D channel 106 may include one or more Group III-VI semiconductors, such as indium selenide (InSe), or one or more oxide semiconductors, such as bismuth oxyselenide (BiOSe).

The stressed source/drain contacts 108 include multiple stressed metal layers 110a-c (e.g., over the channel in the source/drain regions), which are designed to induce strain in the 2D channel 106. In the illustrated embodiment, the metal layers 110a-c include a contact metal 110a (e.g., gold (Au)), an adhesive metal 110b (e.g., titanium (Ti)), and a stressor metal 110c (e.g., nickel (Ni)). The contact metal 110a is in contact with the channel 106, the adhesive metal 110b provides adhesion between the contact metal 110a and the stressor metal 110c, and the stressor metal 110c is engineered with internal stress. In this manner, the internal stress of the stressor metal 110c exerts stress on the other metal layers 110a,b, which in turn exert stress on the 2D channel 106.

The stress exerted on the 2D channel 106 by the source/drain contacts 108 induces strain in the channel 106, such as uniaxial tensile or compressive strain, which alters the atomic structure of the 2D channel 106 to increase carrier mobility. In this manner, carrier mobility in the 2D channel 106 is improved by inducing strain in the channel 106 through strategic metal engineering in the source/drain contacts 108.

Stress may refer to the force per unit area applied to a material,

$$stress = \frac{force}{area} ,$$

measured in units of pascals (Pa) or megapascals (MPa). There are various types of stress, including tensile stress (e.g., pulling or stretching force) and compressive stress (e.g., pushing or squeezing force), among others. Moreover, stress can be uniaxial (e.g., exerted along a single axis or direction), biaxial (e.g., exerted along two axes or directions), or triaxial (e.g., exerted along all three axes or directions).

Strain may refer to the deformation per unit length that occurs in a material when subjected to stress,

$$strain = \frac{change in length}{original length} ,$$

expressed as a percentage. There are various types of strain, including tensile strain (e.g., where a material stretches) and compressive strain (e.g., where a material contracts), among others. Moreover, strain can be uniaxial (e.g., induced along a single axis or direction), biaxial (e.g., induced along two axes or directions), or triaxial (e.g., induced along all three axes or directions).

The source/drain contacts 108 can be strategically engineered to exert an appropriate type and amount of stress (e.g., uniaxial tensile or compressive stress) on the channel 106 to induce the requisite strain in the channel 106 for purposes of increasing carrier mobility. In particular, the stress exerted by the source/drain contacts 108 can be tuned using different types, numbers, arrangements, and geometries of metal 110 in the source/drain contacts 108.

In some embodiments, for example, the source/drain contacts 108 may include a layer of stressed nickel (Ni) 110 (e.g., as the stressor metal 110c). For example, the layer of nickel 110 may be formed with a tunable type and amount of stress by depositing nickel film using electron beam (e-beam) evaporation. In particular, the internal stress in e-beam evaporated nickel can be tuned by adjusting deposition conditions (e.g., deposition rate, power (watts), temperature, pressure), film thickness (e.g., the height of the stressed metal layer 110), material composition (e.g., gas ratios of the deposited film), and so forth. In this manner, the resulting nickel layer 110 can be engineered with the requisite stress to induce strain in the 2D channel 106 for the purpose of increasing carrier mobility. As an example, the nickel layer 110 can be tuned with a particular amount of tensile stress to induce tensile strain in a 2D channel 106 containing one or more TMDs, such as monolayer or multilayer molybdenum disulfide (MoS₂), which stretches the TMD-based channel 106 and increases carrier mobility. In other embodiments, other metals may be used as stressors instead of, or in addition to, nickel, such as tungsten and/or titanium.

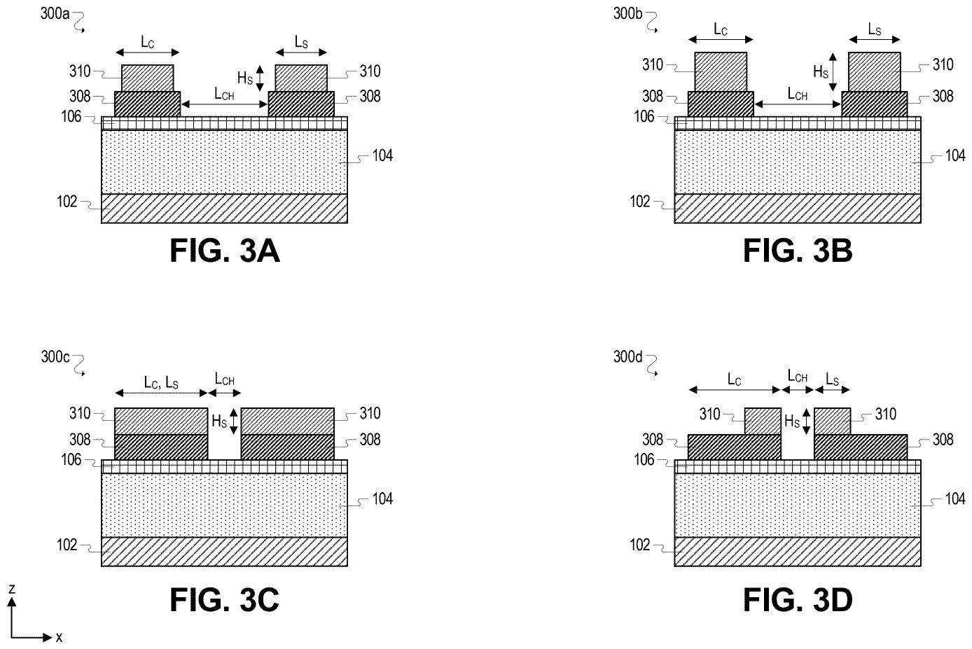

In various embodiments, the types of metal in the metal layers 110, along with the number, arrangement, and geometry (e.g., shape, dimensions) of the metal layers 110, may vary based on various considerations, including the type of 2D material in the channel 106, the type and amount of strain required to increase carrier mobility in the 2D channel material 106, the source/drain contact 108 length (L_{C}), the channel 106 length (L_{CH}), etc. Examples of strained 2D transistors 300a-d with stressed source/drain contacts 108 in varying configurations are shown and described further in connection with FIGS. 3A-D.

In operation, when a gate voltage (VG) is applied to the gate electrode 102 (e.g., doped silicon), an electric field is generated across the gate dielectric 104 (e.g., SiO₂), which modulates carrier density in the strained 2D channel 106 (e.g., MoS₂ or other TMDs) to control the conductivity of the channel 106 (e.g., allowing or preventing current flow through the channel 106). In this manner, the gate voltage (VG) regulates current flow between the source and drain contacts 108.

Due to strain engineering in the source/drain contacts 108, metal-contact-induced strain in the 2D channel 106 increases carrier mobility in the channel 106, which enables high-performance 2D field-effect transistors (FETs) and ferroelectric FETs (FeFETs). In particular, the increased carrier mobility in the strained 2D channel 106 leads to higher on-current (ION), higher transconductance (gₘ), and a negative threshold voltage (V_{T}) shift in transistor 100. Moreover, the increase in on-current (ION) is higher for short-channel devices (e.g., transistors with a channel length (L_{CH}) of 200 nm or less).

The source/drain contacts 108 and underlying metal layers 110 may include any suitable type or combination of conductive materials or metals, including, without limitation, nickel (Ni), iridium (Ir), ruthenium (Ru), antimony (Sb), bismuth (Bi), indium (In), titanium (Ti), tungsten (W), gold (Au), palladium (Pd), platinum (Pt), molybdenum (Mo), scandium (Sc), or chromium (Cr). In some embodiments, for example, the source/drain contact metal 110a may include nickel (Ni), iridium (Ir), or ruthenium (Ru) if the 2D channel 106 includes tungsten disulfide (WSe₂). Alternatively, in some embodiments, the source/drain contact metal 110a may include antimony (Sb), bismuth (Bi), indium (In), or nickel (Ni) if the 2D channel 106 includes molybdenum disulfide (MoS₂). In some embodiments, the adhesive metal 110b may include titanium (Ti) or any other suitable metal for providing adhesion between other source/drain metal layers 110a,c. Alternatively, in some embodiments, the adhesive metal 110b may be omitted and the stressor metal(s) 110c may be formed directly on the contact metal 110a. In some embodiments, the stressor metal 110c may include nickel (Ni), tungsten (W), ruthenium (Ru), platinum (Pt), or molybdenum (Mo). In some embodiments, the source/drain contacts 108 and underlying metal layers 110 may include any suitable type or amount of stress.

In some embodiments, the source/drain contacts 108 may have a length in the range of about 200 nanometers (nm) to 2 microns. In some embodiments, each metal layer 110 may have a thickness in the range of about 5 nm to 100 nm. In some embodiments, at least one of the metal layers 110 (e.g., the upper stressor metal layer 110c) may have a thickness in the range of about 50 nm to 100 nm. In some embodiments, the collection of metal layers 110 may have a combined thickness in the range of about 50 nm to 150 nm.

In the illustrated embodiment, transistor 100 is symmetric, and each source/drain contact 108 can serve as either a source contact or a drain contact (e.g., with one serving as a source contact 108 and the other serving as a drain contact 108).

The 2D channel 106 may include any suitable type or combination of 2D materials, including, without limitation, transition metal dichalcogenides (TMDs), graphene, and/or 2D oxides. In various embodiments, the 2D materials may be monolayer or multilayer (e.g., few layer) 2D materials. In some embodiments, the 2D channel 106 may include multiple layers of TMDs, such as a first TMD layer and a second doped or alloyed TMD layer between the first TMD layer and the source/drain contacts 108.

TMDs may refer to atomically thin semiconductors of the type MX₂, where M is a transition metal atom (e.g., molybdenum (Mo), tungsten (W)) and X is a chalcogen atom (e.g., sulfur(S), selenium (Se), tellurium (Te)). Examples of TMDs include molybdenum disulfide (MoS₂), tungsten disulfide (WS₂), molybdenum diselenide (MoSe₂), tungsten diselenide (WSe₂), molybdenum ditelluride (MoTe₂), and tungsten ditelluride (WTe₂). Thus, in some embodiments, the 2D channel 106 may include a TMD with elements such as (i) molybdenum or tungsten, and (ii) sulfur, selenium, or tellurium.

Graphene may refer to a single layer or monolayer of carbon (C) atoms arranged in a hexagonal (e.g., honeycomb) lattice. Thus, in some embodiments, the 2D channel 106 may include a 2D material with carbon (C) elements.

2D oxides may refer to atomically thin metal oxide compounds. Thus, in some embodiments, the 2D channel 106 may include a 2D material with metal and oxygen (O) elements.

In various embodiments, the 2D channel 106 may be undoped, or alternatively, the 2D channel 106 may be doped at each end (e.g., below the source/drain contacts 108 in the source/drain regions). In some embodiments, the channel may have a length in the range of about 50 nm to 2 microns. Moreover, the 2D material may be strained, such as uniaxially tensile strained or uniaxially compressive strained.

The gate electrode 102 may include any suitable type or combination of conductive materials, including, without limitation, doped silicon and/or metals. In some embodiments, doped silicon may include p-doped silicon (e.g., silicon (Si) doped with a p-type dopant such as boron (B), aluminum (Al), or gallium (Ga)) or n-doped silicon (e.g., silicon (Si) doped with an n-type dopant such as phosphorus (P), arsenic (As), or antimony (Sb)). Thus, in some embodiments, the gate electrode 102 may include elements such as (i) silicon and (ii) boron, aluminum, or gallium. Alternatively, the gate electrode 102 may include elements such as (i) silicon and (ii) phosphorus, arsenic, or antimony. Alternatively, the gate electrode 102 may include one or more metal elements.

The gate dielectric 104 may include any suitable type or combination of dielectric materials, including, without limitation, silicon dioxide (SiO₂) or high-k dielectrics such as magnesium oxide (MgO) or tungsten trioxide (WO₃). Thus, in some embodiments, the gate dielectric 104 may include elements such as (i) silicon, magnesium, or tungsten and (ii) oxygen. In some embodiments, the gate dielectric 104 may have a thickness in the range of about 20 nm to 300 nm, including a thickness of about 90 nm in some embodiments.

The remaining areas of transistor 100 may be filled with one or more dielectrics (not shown).

It should be appreciated that transistor 100 is merely an example embodiment and numerous other embodiments are also within the scope of this disclosure. In various embodiments, for example, certain elements of transistor 100 may be modified, replaced, rearranged, omitted, and/or added. For example, transistor 100 may be implemented as any suitable type of transistor, including, without limitation, a planar field-effect transistor (FET), finFET, ferroelectric FET (FeFET), ribbonFET, gate-all-around (GAA) transistor, bi-gate transistor, or tri-gate transistor, among other examples. In various embodiments, the materials used in each layer of transistor 100 may differ from those described above. In actual embodiments, transistor 100 may include additional connections (not shown) to the source/drain contacts 108 and the back gate electrode 102, such as top vias connecting the source/drain contacts 108 to an interconnect above the transistor 100, and a bottom via connecting the gate electrode 102 to an interconnect below the transistor 100.

In some embodiments, one or more transistors 100 may be used to implement circuitry (e.g., processing circuitry, memory circuitry, storage circuitry, or communication circuitry) in an integrated circuit (IC) (e.g., an IC die or package), which may be attached to a circuit board and/or incorporated into an electronic device or system. Transistor 100, along with any device that incorporates transistor 100 (e.g., an IC die, chip, package), may also be referred to as a semiconductor device.

The concepts described above for transistor 100, including any modifications thereof, also apply to the other embodiments in this disclosure (e.g., transistors 300a-d, 400, 600, 800), and vice versa.

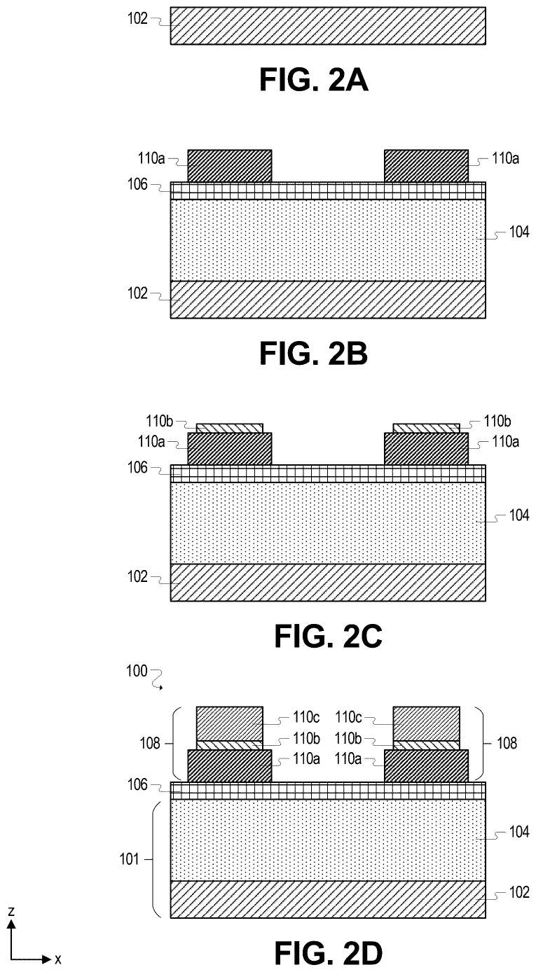

FIGS. 2A-D illustrate an example process flow for forming a 2D transistor 100 with a strained channel 106 induced by stressed source/drain contacts 108. In the illustrated example, FIGS. 2A-D show cross-section (x-z plane) views after performing various steps of the process flow. It will be appreciated in light of the present disclosure that the illustrated process flow is only one example methodology for arriving at 2D transistor 100.

In FIG. 2A, a substrate 102 is received (e.g., a wafer-level or unit-level substrate). In some embodiments, the substrate 102 may include doped silicon, such as silicon doped heavily with p-type or n-type dopants. Alternatively, in some embodiments, the substrate 102 may include undoped silicon, and the substrate 102 may subsequently be doped heavily with p-type or n-type dopants.

In the illustrated embodiment, the substrate 102 serves as the gate electrode for a back-gated transistor 100. The substrate 102 also serves as the underlying substrate on which the back-gated transistor 100 will be fabricated.

In FIG. 2B, a 2D back-gated transistor stack is formed over the substrate 102 (e.g., using e-beam lithography). In particular, a gate dielectric 104 is formed over the substrate/gate electrode 102, a 2D channel 106 is formed over the gate dielectric 104, and contact metals 110a are formed in source/drain regions over the 2D channel 106.

In some embodiments, the gate dielectric 104 may include a layer of SiO₂ (e.g., thermal SiO₂ with a thickness of about 90 nm). The 2D channel 106 may include one or more layers of 2D material(s) (e.g., TMDs such as MoS₂ or WS₂, Group III-VI semiconductors such as InSe, or oxide semiconductors such as BiOSe), which may be grown using chemical vapor deposition (CVD). The contact metals 110a may include a layer of any suitable metal (e.g., gold (Au), nickel (Ni), iridium (Ir), ruthenium (Ru), antimony (Sb), bismuth (Bi), indium (In)).

In FIG. 2C, adhesive metals 110b are formed over the contact metals 110a. The adhesive metals 110b are used to provide adhesion between the contact metals 110a and stressor metals 110c that will be formed over the adhesive metals 110b. The adhesive metals 110b may include a layer of any suitable metal (e.g., titanium (Ti)).

In FIG. 2D, stressor metals 110c are formed over the adhesive metals 110b. The stressor metals 110c may include a layer of any suitable metal (e.g., nickel (Ni)), and the stressor metals 110c may be formed by depositing metal film over the adhesive metals 110b using any suitable deposition method (e.g., e-beam evaporation).

Moreover, the stressor metals 110c may be engineered with a particular type and amount of internal stress (e.g., about 600 MPa of uniaxial tensile stress) in order to strain the 2D channel 106 and increase carrier mobility. In some embodiments, for example, the internal stress in the stressor metals 110c may be tuned by adjusting deposition conditions (e.g., deposition method/type, deposition rate, power, temperature, pressure), film thickness (e.g., thickness/height of stressor metal layers 110c), material composition (e.g., gas ratios of the deposited film), and so forth.

The metal layers 110a-c collectively form stressed source/drain contacts 108, which are designed to induce strain in the 2D channel 106. For example, the stressor metal 110c is engineered with internal stress, the adhesive metal 110b provides adhesion between the stressor metal 110c and the contact metal 110a, and the contact metal 110a is in contact with the channel 106. In this manner, the internal stress of the stressor metal 110c exerts stress on the other metal layers 110a,b, which in turn exert stress on the 2D channel 106. Moreover, the stress exerted on the 2D channel 106 induces strain in the channel 106, which alters the atomic structure of the 2D channel 106 to increase carrier mobility.

The completed transistor 100 includes a strained 2D channel 106, a back gate 101 (e.g., with gate electrode 102 and gate dielectric 104) below the channel 106, and stressed source/drain contacts 108 (e.g., with stressed metal layers 110a-c) above the channel 106.

At this point, any remaining processing may be performed, such as dielectric filling/planarization, patterning vias to the source/drain contacts 108 and gate 102, interconnect patterning (e.g., metallization), interconnect bump formation, backside processing, singulation, packaging, etc. For example, in wafer-level or panel-level process flows, the completed wafer or panel may be diced to singulate integrated circuit (IC) dies on the wafer or panel. The singulated IC dies may then be incorporated into an IC package, circuit board, electronic device, system, etc.

FIGS. 3A-D illustrate cross-section (x-z plane) views of strained 2D transistors 300a-d with stressed source/drain contacts 308 in varying configurations. In the illustrated examples, the amount of stress exerted by the metal stressors 310 on the source/drain contacts 308 and the channel 106 is tuned by varying certain aspects of transistors 300a-d, such as the size and position of the source/drain metal contacts 308 (e.g., contact length (L_{C}), position), metal stressors 310 (e.g., stressor length (L_{S}), height (H_{S}), position), and channel 106 (e.g., channel length (L_{CH})). In particular, the stressor metals 310 and source/drain contacts 308 can be patterned in particular geometries and positions to engineer the stress exerted on the 2D channel 106. For example, the amount of engineered stress can be increased by increasing the thickness/height of the stressor metals 310 (e.g., stressor height (H_{S})), the length of the source/drain contacts 308 and/or stressor metals 310 (e.g., contact length (L_{C}), stressor length (L_{S})), etc. Moreover, the increase in carrier mobility in the channel 106 caused by contact-induced strain can be tuned by adjusting the channel length (L_{CH}), as short channel devices exhibit a higher increase in carrier mobility due to strain.

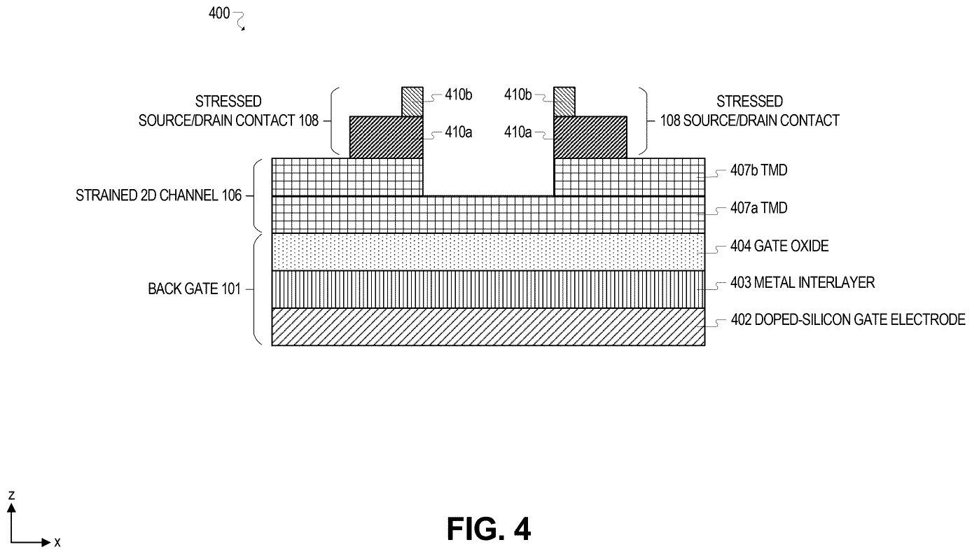

FIG. 4 illustrates a cross-section (x-z plane) view of another strained 2D transistor 400 with stressed source/drain contacts 108. In particular, stress from the source/drain contacts 108 induces strain in the 2D channel 106, which increases carrier mobility in the channel 106, as described further below.

In the illustrated embodiment, transistor 400 is a back-gated strained 2D transistor, which includes a strained 2D channel 106, stressed source/drain contacts 108 over (e.g., above) opposite ends of the channel 106 on the frontside (e.g., such that the channel 106 extends between the source/drain contacts 108), and a back gate 101 over (e.g., below) the channel 106 on the backside.

The back gate 101 includes a doped-silicon gate electrode 402, a metal interlayer 403, and a gate oxide 404. The metal interlayer 403 is between the doped-silicon gate electrode 402 and the gate oxide 404, and the gate oxide 404 is between the gate electrode 402/metal interlayer 403 and the channel 106. In some embodiments, the doped-silicon gate electrode 402 may include heavily doped silicon, such as heavily p-doped silicon (p++Si) or heavily n-doped silicon (n++Si). In some embodiments, the heavily doped silicon gate electrode 402 may be a silicon substrate on which the transistor 400 is fabricated. The gate oxide 404 may include any suitable oxide, such as silicon dioxide (e.g., SiO₂). In some embodiments, the gate oxide 404 may additionally or alternatively include one or more dipole shifting layers (e.g., for threshold voltage (V_{T}) centering), such as magnesium oxide (e.g., MgO) for NMOS and tungsten oxide (e.g., WO₃) for PMOS. The metal interlayer 403 may include any suitable conductive material or metal. The metal interlayer 403 may provide various benefits, including optimized electrostatic control, reduced charge trapping, enhanced carrier injection, and improved overall device stability. In embodiments where transistor 400 is a ferroelectric FET (FeFET), the back gate 101 may additionally include a ferroelectric layer (not shown) between the gate electrode 402 and the gate oxide 404 (e.g., instead of, or in addition to, the metal interlayer 403).

The strained 2D channel 106 includes multiple layers of transition metal dichalcogenides (TMDs) 407a-b (e.g., molybdenum disulfide (MoS₂) or tungsten disulfide (WS₂)). In some embodiments, for example, the 2D channel 106 may include a first TMD layer 407a-b and a second doped or alloyed TMD layer 407b between the first TMD layer 407a and the source/drain contacts 108. In other embodiments, the strained 2D channel 106 may alternatively or additionally include layers of other 2D semiconductor materials 407a-b, such as Group III-VI semiconductors (e.g., indium selenide (InSe)) or oxide semiconductors (e.g., bismuth oxyselenide (BiOSe)).

The stressed source/drain contacts 108 include multiple stressed metal layers 410a-b (e.g., over the channel in the source/drain regions), which are designed to induce strain in the 2D channel 106. In the illustrated embodiment, the metal layers 410a-b include a contact metal 410a and a stressor metal 410b (which may respectively include any of the metals discussed above for contact metal 110a and stressor metal 110c of transistor 100). The contact metal 410a is in contact with the channel 106 (e.g., in the source/drain regions), and the stressor metal 410b is engineered with internal stress. In this manner, the internal stress of the stressor metal 410b exerts stress on the contact metal 410a, which in turn exerts stress on the 2D channel 106.

In the illustrated embodiment, the stressor metal 410b is patterned with a particular geometry and position (e.g., with smaller dimensions than the contact metal 410a and positioned on the inner edge of the contact metal 410a) to engineer or tune the amount of stress exerted on the contact metal 410a, and in turn, on the 2D channel 106. In this manner, the appropriate amount of stress is exerted on the TMD layers 407a-b in the 2D channel 106 in order to strain the TMDs 407a-b and increase carrier mobility in the channel 106, thus boosting FET performance.

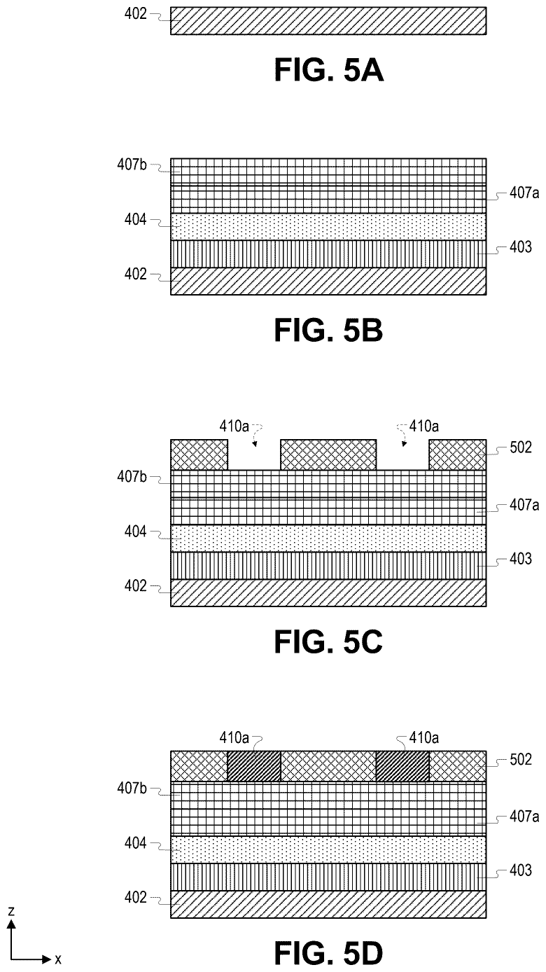

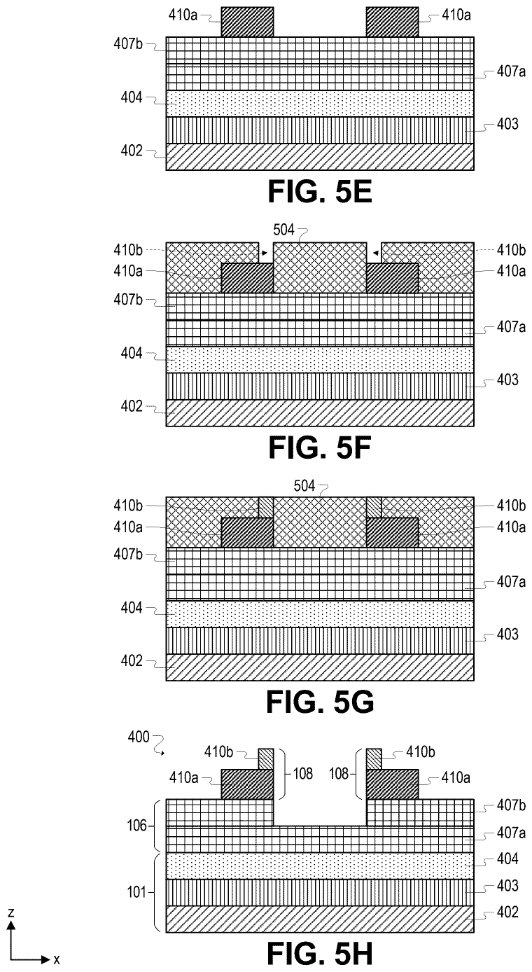

FIGS. 5A-H illustrate another example process flow for forming a strained 2D transistor 400 with stressed source/drain contacts 108. In the illustrated example, FIGS. 5A-H show cross-section (x-z plane) views after performing various steps of the process flow. It will be appreciated in light of the present disclosure that the illustrated process flow is only one example methodology for arriving at 2D transistor 400.

In FIG. 5A, a substrate 102 is received (e.g., a wafer-level or unit-level substrate). In some embodiments, the substrate 102 may include doped silicon, such as silicon doped heavily with p-type or n-type dopants. Alternatively, in some embodiments, the substrate 102 may include undoped silicon, and the substrate 102 may subsequently be doped heavily with p-type or n-type dopants. In the illustrated embodiment, the substrate 102 serves as the gate electrode for a back-gated transistor 100. The substrate 102 also serves as the underlying substrate on which the back-gated transistor 100 will be fabricated.

In FIG. 5B, a 2D heterostructure is formed on the substrate 402. In particular, the 2D heterostructure includes a metal interlayer 403, a gate oxide 404, and multiple 2D TMD layers 407a-b. The metal interlayer 403 is formed over the doped-silicon substrate 402, the gate oxide 404 is formed over the metal interlayer 403, and the TMD layers 407a-b are formed over the gate oxide 404.

In FIG. 5C, lithographical patterning is performed for the source/drain contact metal layers 410a. In particular, a photoresist layer 502 is formed over the TMDs 407a-b, and the photoresist layer 502 is patterned (e.g., etched) to remove portions of the photoresist layer 502 in areas where the source/drain contact metal layers 410a will be formed.

In FIG. 5D, metal is deposited to form the source/drain contact metal layers 410a.

In FIG. 5E, the photoresist layer 502 is removed.

In FIG. 5F, lithographical patterning is performed for the source/drain stressor metal layers 410b and the channel 106. In particular, a photoresist layer 504 is formed over the 2D heterostructure, and the photoresist layer 504 is patterned (e.g., etched) to remove portions of the photoresist layer 504 in areas where the source/drain stressor metal layers 410b will be formed. The area between the portions of the photoresist layer 504 that were removed (e.g., for the stressor metals 410b) is where the channel 106 will be patterned.

In FIG. 5G, metal is deposited to form the source/drain stressor metal layers 410b.

In FIG. 5H, the photoresist layer 504 is removed. Moreover, a plasma process is performed to etch or oxidize a portion of the upper TMD layer 407b in the channel area 106 between the source/drain contacts 108, and that portion of the upper TMD layer 407b is removed.

The completed transistor 400 includes a strained 2D channel 106 (e.g., with TMD layers 407a-b), a back gate 101 (e.g., with silicon-doped gate electrode 402, metal interlayer 403, and gate oxide 404) below the channel 106, and stressed source/drain contacts 108 (e.g., with stressed metal layers 410a-b) above the channel 106.

At this point, any remaining processing may be performed, such as dielectric filling/planarization, patterning vias to the source/drain contacts 108 and gate 402, interconnect patterning (e.g., metallization), interconnect bump formation, backside processing, singulation, packaging, etc. For example, in wafer-level or panel-level process flows, the completed wafer or panel may be diced to singulate integrated circuit (IC) dies on the wafer or panel. The singulated IC dies may then be incorporated into an IC package, circuit board, electronic device, system, etc.

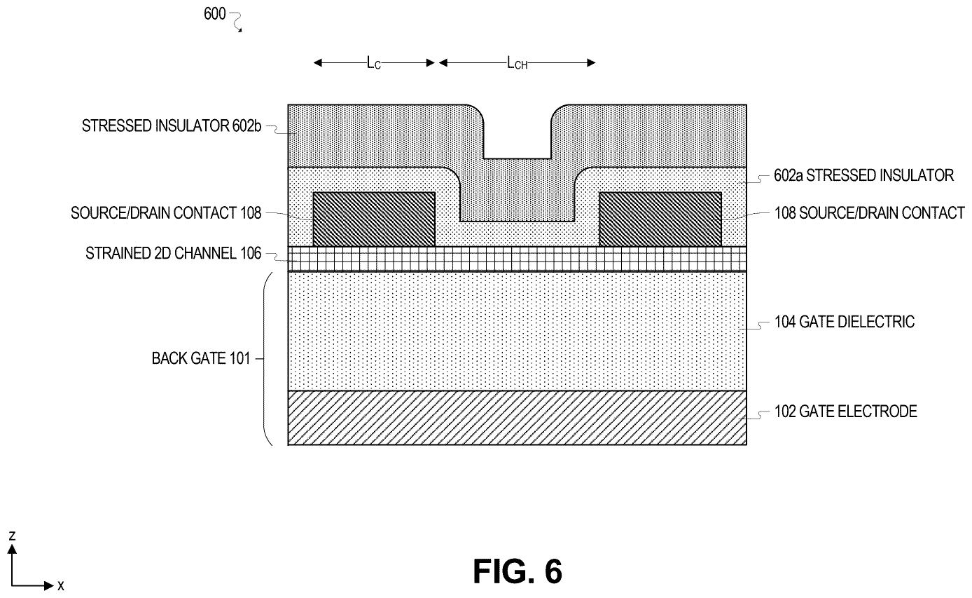

FIG. 6 illustrates a cross-section (x-z plane) view of a 2D transistor 600 with a strained channel 106 induced by stressed insulators 602a-b. In particular, stress from the insulators 602a-b induces strain in the 2D channel 106, which increases carrier mobility in the channel 106, as described further below.

In the illustrated embodiment, transistor 600 is similar to transistor 100, except transistor 600 includes multiple layers of stressed insulators 602a-b over (e.g., above) the channel 106 and the source/drain contacts 108 (e.g., instead of source/drain contacts 108 engineered with stressed metal layers 110a-c).

The stressed insulators 602a-b are engineered with internal stress to induce the requisite strain in the 2D channel 106 in order to increase carrier mobility. In particular, the stress-engineered insulators 602a-b are designed to exert stress on the 2D materials in the channel 106 (e.g., directly and indirectly through the source/drain contacts 108), which induces strain in the 2D channel 106 (e.g., uniaxial tensile or compressive strain). The strain induced in the 2D channel 106 alters the atomic structure of the 2D channel 106, which causes an increase in carrier mobility in the channel 106.

The stressed insulators 602a-b can be strategically engineered to exert an appropriate type and amount of stress (e.g., uniaxial tensile or compressive stress) on the channel 106 to induce the requisite strain in the channel 106 for purposes of increasing carrier mobility. In particular, the stress exerted by the insulators 602a-b can be tuned by varying the number and arrangement of insulator layers, the type of insulator material in each layer (e.g., material type/composition), layer thickness/height, deposition conditions (e.g., deposition method/type, deposition rate, power, temperature, pressure), and so forth. The particular type and amount of stress may depend on various considerations, including the type of 2D material in the channel 106, the type and amount of strain required to increase carrier mobility in the 2D channel material 106, the channel 106 length (L_{CH}), etc.

In the illustrated embodiment, transistor 600 is capped with multiple insulator layers 602a-b over the channel 106 and the source/drain contacts 108. Moreover, one or more of the insulator layers 602a-b may be engineered with a particular type and amount of internal stress. As an example, the insulator layers 602a-b may include a first layer of aluminum oxide (AlOₓ) 602a over the channel 106 and the source/drain contacts 108, followed by a second layer of silicon nitride (SiNₓ) 602b over the first layer of aluminum oxide (AlOₓ) 602a. Moreover, the upper silicon nitride (SiNₓ) layer 602b may be engineered with about 600 MPa of uniaxial tensile stress. In this manner, the stressed SiNₓ layer 602b exerts stress on the AlOₓ layer 602a, which in turn exerts stress on the source/drain contacts 108 and the 2D channel 106. The stress exerted on the channel 106 strains the 2D material in the channel 106, which causes an increase in carrier mobility in the channel 106.

In this manner, the stress-engineered insulators 602a-b are used to increase carrier mobility in the 2D channel 106 through insulator-induced strain in the channel 106, which improves performance and enables high-performance 2D FETs and FeFETs. In particular, the increased carrier mobility in the strained 2D channel 106 leads to higher on-current (ION), higher transconductance (gₘ), and a negative threshold voltage (V_{T}) shift in transistor 600. Moreover, the increase in on-current (ION) is higher for short-channel devices (e.g., transistors with a channel length (L_{CH}) of 200 nm or less). Moreover, the use of stress-engineered insulators 602a-b to enhance carrier mobility is an industry compatible approach that can be used for CMOS-compatible strain engineering.

The insulator layers 602 may include any suitable type or combination of insulators (e.g., materials that inhibit the flow of electric current), including, without limitation, dielectrics such as silicon nitride (e.g., SiN), aluminum oxide (e.g., Al₂O₃), aluminum nitride (e.g., AlN), hafnium oxide (e.g., HfO₂), and zirconium oxide (e.g., ZrO₂). Thus, in some embodiments, the respective insulator layers 602 may include elements such as (i) silicon and nitrogen; (ii) aluminum and oxygen; (iii) aluminum and nitrogen; (iv) hafnium and oxygen; or (v) zirconium and oxygen. In some embodiments, for example, the insulator layers 602 may include a first dielectric layer with silicon and nitrogen (e.g., SiN), and a second dielectric layer with aluminum and oxygen (e.g., AlO). Moreover, some or all of the insulator layers 602 may include any suitable type or amount of internal stress. In some embodiments, each insulator layer 602 may have a thickness in the range of about 10 nm to 75 nm. In some embodiments, at least one of the insulator layers 602 (e.g., the upper stressor insulator layer 602b) may have a thickness in the range of about 50 nm to 75 nm. In some embodiments, the collection of insulator layers 602a-b may have a combined thickness in the range of about 50 nm to 100 nm. Insulator layers 602 may be referred to as insulators, stressed insulators, insulator layers, insulator caps, dielectrics, stressed dielectrics, dielectric layers, dielectric caps, and variations thereof.

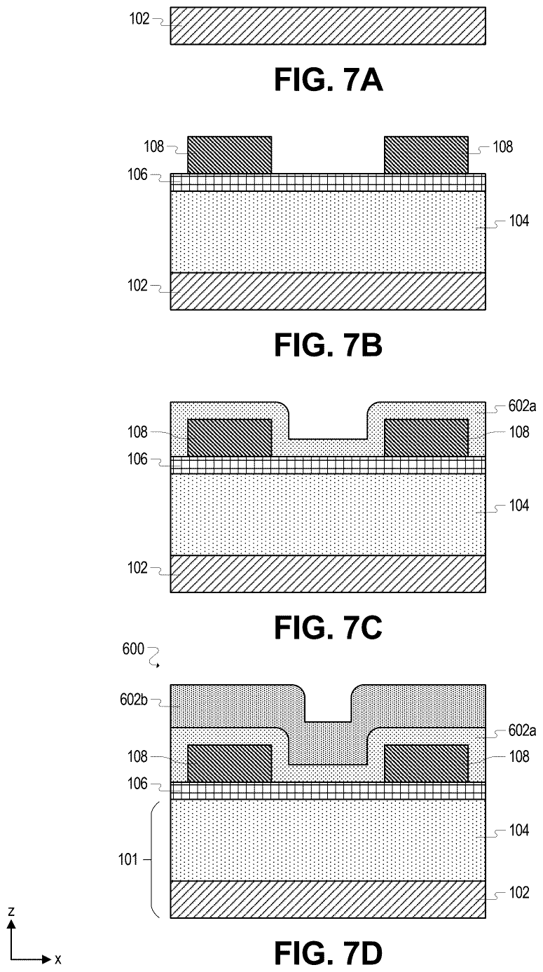

FIGS. 7A-D illustrate an example process flow for forming a 2D transistor 600 with a strained channel 106 induced by stressed insulators 602a-b. In the illustrated example, FIGS. 7A-D show cross-section (x-z plane) views after performing various steps of the process flow. It will be appreciated in light of the present disclosure that the illustrated process flow is only one example methodology for arriving at 2D transistor 600.

In FIG. 7A, a substrate 102 is received (e.g., a wafer-level or unit-level substrate). In some embodiments, the substrate 102 may include doped silicon, such as silicon doped heavily with p-type or n-type dopants. Alternatively, in some embodiments, the substrate 102 may include undoped silicon, and the substrate 102 may subsequently be doped heavily with p-type or n-type dopants.

In the illustrated embodiment, the substrate 102 serves as the gate electrode for a back-gated transistor 100. The substrate 102 also serves as the underlying substrate on which the back-gated transistor 100 will be fabricated.

In FIG. 7B, a 2D back-gated transistor stack is formed over the substrate 102 (e.g., using e-beam lithography). In particular, a gate dielectric 104 is formed over the substrate/gate electrode 102, a 2D channel 106 is formed over the gate dielectric 104, and source/drain contacts 108 are formed in source/drain regions over the 2D channel 106.

In some embodiments, the gate dielectric 104 may include a layer of SiO₂ (e.g., thermal SiO₂ with a thickness of about 90 nm). The 2D channel 106 may include one or more layers of 2D material(s) (e.g., TMDs such as MoS₂ or WS₂), which may be grown using chemical vapor deposition (CVD). The source/drain contacts 108 may include one or more layers of any suitable conductive material or metal (e.g., gold (Au)).

In FIG. 7C, the transistor stack is encapsulated with an insulator layer 602a. The insulator layer 602a may be formed by depositing any suitable insulator over the transistor stack (e.g., over the source/drain contacts 108 and the channel 106). In some embodiments, for example, the transistor stack may be encapsulated with a layer of aluminum oxide (AlOₓ) 602a (e.g., Al seed+10 nm AlOₓ).

In various embodiments, the insulator layer 602a may be engineered with a particular type and amount of internal stress, and/or the insulator layer 602a may become stressed due to stress exerted by other subsequently formed insulator layers (e.g., layer 602b) that are engineered with internal stress.

In FIG. 7D, the transistor stack is encapsulated with another insulator layer 602b. The second insulator layer 602b may be formed by depositing any suitable insulator over the transistor stack (e.g., over the first insulator layer 602a). In some embodiments, for example, the transistor stack may be encapsulated with a layer of stressed silicon nitride (SiNₓ) 602b (e.g., SiNₓ with a thickness of 50-75 nm and 600 MPa of uniaxial tensile stress).

In this manner, the stressed SiNₓ layer 602b exerts stress on the AlOₓ layer 602a, which in turn exerts stress on the source/drain contacts 108 and the 2D channel 106. The stress exerted on the channel 106 strains the 2D material in the channel 106, which causes an increase in carrier mobility in the channel 106.

In general, one or more of the insulator layers 602a,b may be engineered with a particular type and amount of internal stress in order to strain the 2D channel 106 and increase carrier mobility. In some embodiments, the stress exerted by the insulator layers 602a,b may be tuned by varying the number and/or arrangement of insulator layers 602, the type of insulator material in each layer 602 (e.g., material type/composition), layer thickness/height, deposition conditions (e.g., deposition method/type, deposition rate, power, temperature, pressure), and so forth.

The completed transistor 600 includes a strained 2D channel 106, a back gate 101 (e.g., with gate electrode 102 and gate dielectric 104) below the channel 106, source/drain contacts 108 above the channel 106, and multiple stressed insulator layers 602a-b over the source/drain contacts 108 and the channel 106.

At this point, any remaining processing may be performed, such as dielectric filling/planarization, patterning vias to the source/drain contacts 108 and gate 102, interconnect patterning (e.g., metallization), interconnect bump formation, backside processing, singulation, packaging, etc. For example, in wafer-level or panel-level process flows, the completed wafer or panel may be diced to singulate integrated circuit (IC) dies on the wafer or panel. The singulated IC dies may then be incorporated into an IC package, circuit board, electronic device, system, etc.

The steps of the illustrated process flows (e.g., the process flows of FIGS. 2A-D, FIGS. 5A-H, and FIGS. 7A-D) may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal-such as interconnect patterning, forming via openings, and shaping—may be performed using any suitable techniques, such as lithography-based patterning/masking and/or etching.

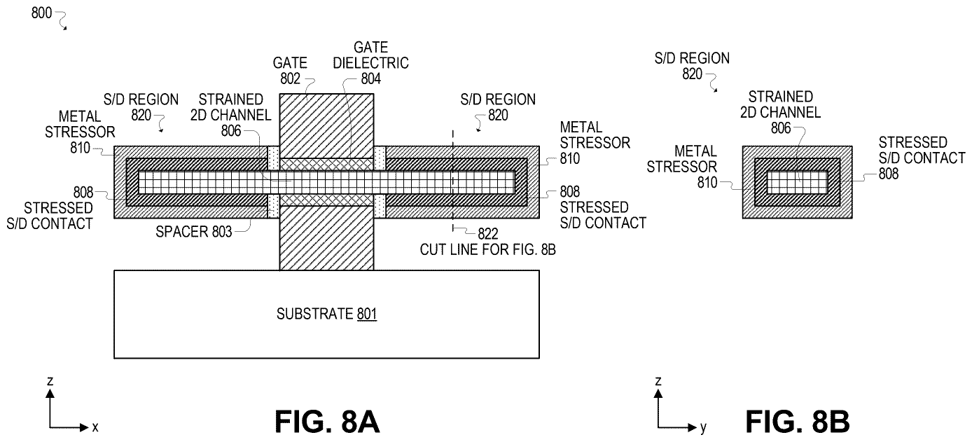

FIGS. 8A-B illustrate a strained 2D gate-all-around (GAA) transistor 800 with stressed source/drain contacts 802. In particular, FIG. 8A shows a cross-section (x-z plane) view of transistor 800, and FIG. 8B shows a transverse cross-section (y-z plane) view of the source/drain regions 820 of transistor 800 (based on the cut line 822 shown in FIG. 8A).

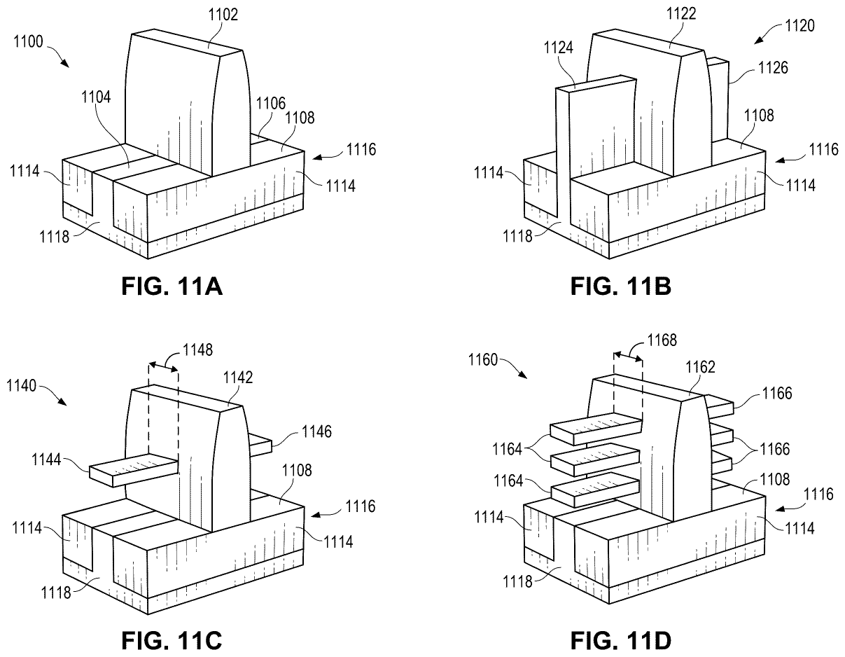

In the illustrated embodiment, transistor 800 is similar to transistors 100, 300a-d, and 400, except transistor 800 is implemented with a gate-all-around (GAA) transistor architecture (e.g., similar to transistor 1140 of FIG. 11C). In particular, transistor 800 includes a strained 2D channel 806, stressed source/drain contacts 808 with metal stressors 810 on opposite ends of the channel 806 (e.g., such that the channel 806 extends between the source/drain contacts 808), a gate 801 and associated gate dielectric 804 surrounding the channel 806, and gate spacers 803 on the sidewalls of the gate 802 (e.g., between the gate 802/gate dielectric 804 and the source/drain regions 820). Moreover, transistor 800 is formed over a substrate 801.

The metal stressors 810 are engineered with internal stress, which causes them to exert stress on the source/drain contacts 808, and in turn, on the 2D channel 806. The stress exerted on the 2D channel 806 induces strain in the channel 806, which increases carrier mobility in the channel 806 and boosts the performance of transistor 800, as described throughout this disclosure.

The stressed source/drain contacts 808 and metal stressors 810 may be implemented using any of the metals described herein in connection with source/drain contacts 108 and metal stressors 110a-c. The 2D channel 806 may be implemented using any of the 2D materials described herein for 2D channel 106. The gate 802 may be implemented using any suitable metal or other conductive material. The gate dielectric 804 may be implemented using any suitable dielectric, including any of the materials described in connection with gate dielectric 104. The substrate 801 may include any suitable material (e.g., silicon).

In general, the embodiments described throughout this disclosure—including the contact-induced strained 2D transistors 100, 300a-d, 400, 800 of FIGS. 1, 3A-D, 4, and 8A-B and the insulator-induced strained 2D transistor 600 of FIG. 6—may be implemented using any transistor architecture, including the planar, FinFET, GAA, and stacked GAA transistor architectures 1100, 1120, 1140, 1160 of FIGS. 11A-D.

In some embodiments, the transistors 100, 300a-d, 400, 600, 800 may be implemented as backend transistors formed during back-end-of-line (BEOL) processing, such as within metal interconnect layers on the frontside or backside of a chip (e.g., within a frontside interconnect or within a backside interconnect for chips with backside power delivery).

### Example Integrated Circuit Embodiments

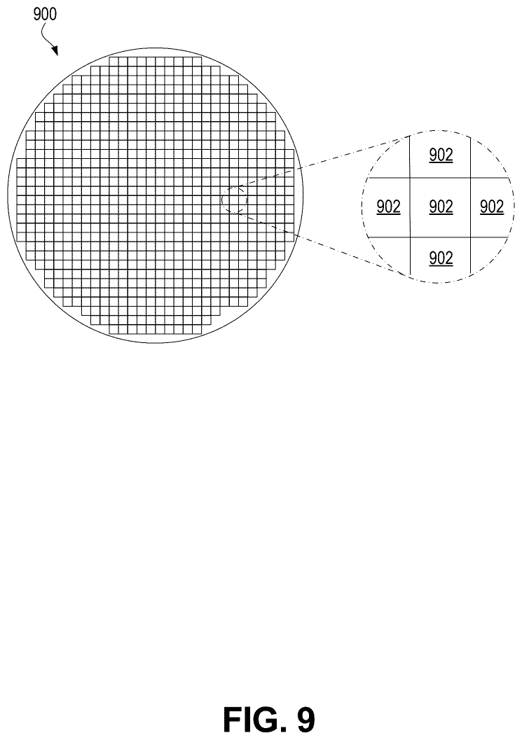

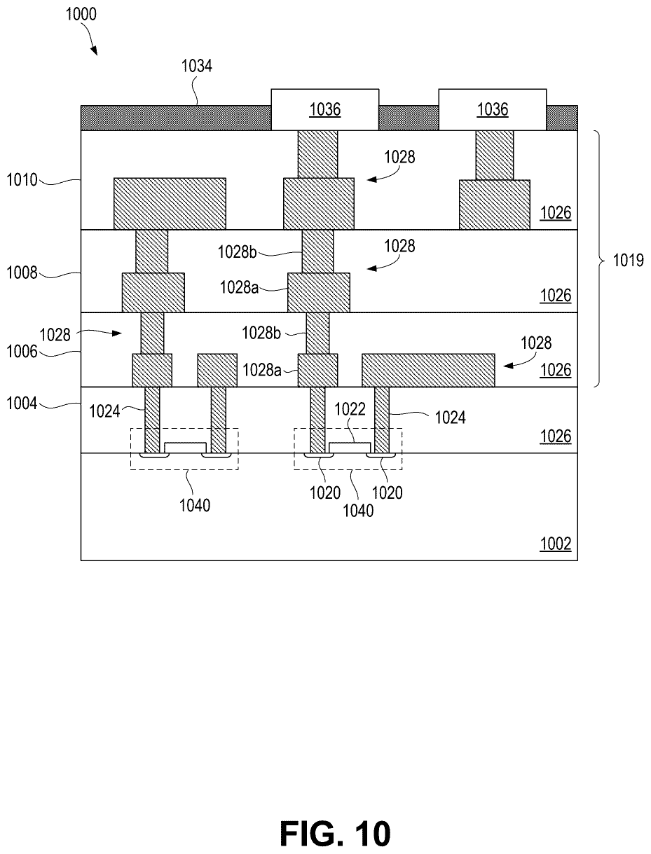

FIG. 9 illustrates a top view of a wafer 900 and dies 902 that may include, or may be included in, any of the embodiments disclosed herein. In some embodiments, for example, the dies 902 may include one or more strained 2D transistors 100, 300a-d, 400, 600, 800. The wafer 900 may be composed of semiconductor material and dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The dies 902 may be any of the dies disclosed herein. The dies 902 may include one or more transistors (e.g., transistors 1040 of FIG. 10, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 900 or the dies 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Some of the embodiments disclosed herein may be manufactured using a die-to-wafer assembly technique in which some dies are attached to a wafer 900 that includes others of the dies, and the wafer 900 is subsequently singulated. Alternatively, or additionally, some of the embodiments disclosed herein may be manufactured using a wafer-to-wafer assembly technique in which multiple wafers 900 with dies 902 are stacked and attached together, and the stack of wafers 900 is subsequently singulated.

FIG. 10 illustrates a cross-sectional view of an integrated circuit structure 1000 that may include, or may be included in, any of the embodiments disclosed herein. In some embodiments, for example, the integrated circuit structure 1000 may include one or more strained 2D transistors 100, 300a-d, 400, 600, 800. Moreover, the integrated circuit structure 1000 may be included in any of the dies disclosed herein (e.g., dies 902). In some embodiments, multiple instances of the integrated circuit structure 1000 may be included in the dies 902. The integrated circuit structure 1000 may be formed on a die substrate 1002. The die substrate 1002 may be a semiconductor substrate composed of semiconductor material including, for example, n-type or p-type materials (or a combination of both). The die substrate 1002 may include, for example, a crystalline substrate formed using a bulk silicon or a silicon-on-insulator (SOI) substructure. In some embodiments, the die substrate 1002 can comprise a layer of silicon on top of an SOI layer with bulk silicon below the SOI layer. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit structure 1000 may be used. The die substrate 1002 may be part of a singulated die (e.g., dies 902 of FIG. 9) or a wafer (e.g., wafer 900 of FIG. 9).

The integrated circuit structure 1000 may include device layer 1004 disposed on the die substrate 1002. The device layer 1004 may include features of transistors 1040 (e.g., metal oxide semiconductor field-effect transistors (MOSFETs)) formed on the die substrate 1002. The transistors 1040 may include, for example, source and drain regions (S/D regions 1020), a gate 1022 to control current flow between the S/D regions 1020, and S/D contacts 1024 to route electrical signals to and from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

FIGS. 11A-11D illustrate perspective views of example planar, FinFET, gate-all-around (GAA), and stacked GAA transistors 1100, 1120, 1140, 1160 that may be incorporated in any of the embodiments disclosed herein. In some embodiments, for example, the planar, FinFET, GAA, and stacked GAA transistors 1100, 1120, 1140, 1160 may be implemented as strained 2D transistors (e.g., similar to transistors 100, 300a-d, 400, 600, 800).

The transistors illustrated in FIGS. 11A-11D are formed on a substrate 1116 having a substrate surface 1108 and a bulk region 1118. Isolation regions 1114 separate the source and drain regions of the transistors from other transistors.

FIG. 11A is a perspective view of an example transistor 1100 comprising a gate 1102 that controls current flow between a source region 1104 and a drain region 1106. The transistor 1100 is planar in that the source region 1104, the drain region 1106 and the substrate surface 1108 lie in the same plane.

FIG. 11B is a perspective view of an example transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1108. The transistor 1120 can be referred to as a FinFET. As the gate 1122 encompasses three sides of the fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a transistor 1140 comprising a gate 1142 that controls current flow between a source region 1144 and a drain region 1146. The transistor 1140 is non-planar in that the source region 1144 and the drain region 1146 lie in a different plane than the substrate surface 1108. As the gate 1142 encompasses all sides of the channel region of the transistor 1140 that extends from the source region 1144 to the drain region 1146, the transistor 1140 can be referred to as a gate-all-around (GAA) transistor.

FIG. 11D is a perspective view of a transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the channel regions of the transistor that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the channel regions extending through the gate.

Returning to FIG. 10, transistors 1040 may include a gate 1022 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as a FinFET 1120, the gate electrode may have an upside-down U-shape that includes a top portion substantially parallel to the surface of the die substrate 1002 and two side portions that are substantially perpendicular to the top surface of the die substrate 1002. In other embodiments, such as a planar FET 1100, at least one of the metal layers that form the gate electrode may be a planar layer that is substantially parallel to the top surface of the die substrate 1002 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse further into the die substrate 1002 may follow the ion implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or information-carrying signals (e.g., input/output (I/O) signals, may be routed to and/or from devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with interconnect structures 1028 of the interconnect layers 1006-1010. The one or more interconnect layers 1006-1010 may form a metallization stack 1019 (which can also be referred to as an “ILD stack” (inter-layer dielectric stack)) of the integrated circuit structure 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit structures having more or fewer interconnect layers than depicted.

In some embodiments, the interconnect structures 1028 may include traces or lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page from the perspective of FIG. 10. The vias 1028b may be arranged to route electrical signals in a direction of a plane that is substantially perpendicular to the surface of the die substrate 1002 upon which the device layer 1004 is formed. In some embodiments, lines 1028a of different interconnect layers 1006-1010 are electrically coupled by vias 1028b.

The interconnect layers 1006-1010 may include a dielectric material 1026 within which the interconnect structures 1028 are disposed, as shown in FIG. 10. In some embodiments, dielectric material 1026 in different ones of the interconnect layers 1006-1010 may have different compositions; in other embodiments, the composition of the dielectric material 1026 between different interconnect layers 1006-1010 may be the same. The device layer 1004 may include a dielectric material 1026 within which the transistors 1040 are disposed and upon which a bottom layer of the metallization stack is located. The dielectric material 1026 that is part of the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (which can be referred to as a Metal 1 or “M1” layer) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (which can be referred to as a Metal 2 or “M2” layer) may be formed directly on the first interconnect layer 1006. In some embodiments, the second interconnect layer 1008 may include vias 1028b to couple the lines 1028a of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (which can be referred to as a Metal 3 or “M3” layer) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit structure 1000 (i.e., farther away from the device layer 1004) may be thicker than the interconnect layers that are lower in the metallization stack 1019, with lines 1028a and vias 1028b in the higher interconnect layers being thicker than those in the lower interconnect layers.

The integrated circuit structure 1000 may include a solder resist material 1034 (e.g., polyimide or similar material) and conductive contacts 1036 formed on the stack of interconnect layers 1006-1010. In FIG. 10, the conductive contacts 1036 are illustrated as taking the form of bond pads. The conductive contacts 1036 may be electrically coupled with interconnect structures 1028 of the top-most layer in the metallization stack 1019 and configured to route electrical signals between the transistors 1040 and components external to the integrated circuit structure 1000. For example, solder bonds may be formed on the conductive contacts 1036 to mechanically and/or electrically couple an integrated circuit component comprising the integrated circuit structure 1000 with another component (e.g., a printed circuit board). The integrated circuit structure 1000 may include additional or alternate structures to route electrical signals from the interconnect layers 1006-1010; for example, the conductive contacts 1036 may include other analogous features (e.g., posts) that can route the electrical signals between the transistors 1040 and external components.

In some embodiments in which the integrated circuit structure 1000 is part of a double-sided die, the integrated circuit structure 1000 may include a second metallization stack (not shown) located on the opposite side of the die substrate 1002 from the device layer 1004. This second metallization stack may include multiple interconnect layers as discussed above with reference to the interconnect layers 1006-1010. Through-silicon vias (TSVs) that extend through the die substrate 1002 can provide electrically conductive pathways from the transistors 1040 to the second metallization stack and the second metallization stack can electrically couple the TSVs to additional conductive contacts (not shown) located on the opposite side of the integrated circuit structure 1000 from the conductive contacts 1036.

In some embodiments, TSVs extending through the die substrate 1002 can be used for routing power and ground signals from conductive contacts located on the opposite side of the integrated circuit structure 1000 from the conductive contacts 1036 to the transistors 1040 and any other components integrated into the integrated circuit structure 1000, and the metallization stack 1019 can be used to route information-carrying signals from the conductive contacts 1036 to transistors 1040 and any other components integrated into the integrated circuit structure 1000. Put another way, the routing of power and ground signals to the transistors 1040 can be separated (via a back-side or bottom-side metallizaton stack and TSVs) from the routing of information-carrying signals to the transistors. The power and ground signals are provided by a backside or bottom-side metallization stack and TSVs (referred to as the backside interconnect), and information-carrying signals are provided by a topside metallization stack (e.g., metallization stack 1019) (referred to as the frontside interconnect). This configuration may be referred to as a backside power delivery architecture.

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

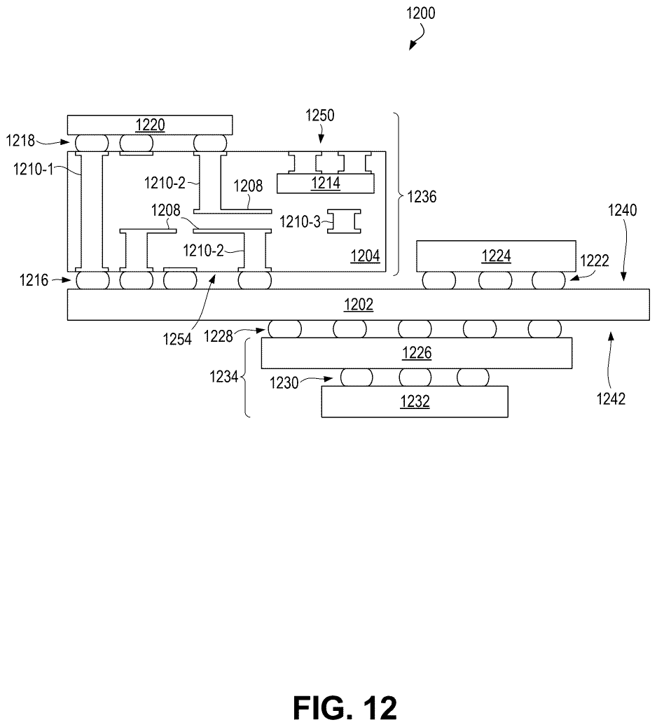

FIG. 12 illustrates a cross-sectional view of an integrated circuit device assembly 1200 that may include any of the embodiments disclosed herein. In some embodiments, for example, the embedded devices 1214 and/or IC components 1220, 1224, 1226, 1232 of the integrated circuit device assembly 1200 may include one or more strained 2D transistors 100, 300a-d, 400, 600, 800. In some embodiments, the integrated circuit device assembly 1200 may be a microelectronic assembly. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and a second face 1242 of the circuit board 1202, the second face 1242 opposing the first face 1240. Generally, components may be disposed on either or both of the first face 1240 and the second face 1242 of the circuit board 1202. Any of the integrated circuit components discussed below with reference to the integrated circuit device assembly 1200 may take the form of any of the embodiments disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 1202. In other embodiments, the circuit board 1202 may be a non-PCB substrate. In some embodiments, the circuit board 1202 may be a circuit board, an interposer, or a package substrate.

The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202 and may include solder balls (as shown in FIG. 12), pins (e.g., as part of a pin grid array (PGA), contacts (e.g., as part of a land grid array (LGA)), hybrid bond interconnect (HBI) pads, male and female portions of a socket, an adhesive, an underfill material, and/or any other suitable electrical and/or mechanical coupling structure. In some embodiments, a coupling component 1216 may also be referred to as a conductive contact. The coupling components 1216 may serve as the coupling components illustrated or described for any microelectronic assembly described herein.

The package-on-interposer structure 1236 may include an integrated circuit component 1220 coupled to an interposer 1204. The interposer 1204 may provide an intervening substrate used to bridge the circuit board 1202 and the integrated circuit component 1220. The integrated circuit component 1220 is coupled to the interposer 1204 by coupling components 1218. The coupling components 1218 may take any suitable form, such as the forms discussed above with reference to the coupling components 1216. Although FIG. 12 shows just one integrated circuit component attached to the interposer, multiple integrated circuit components may be coupled to the interposer 1204. Additional interposers may be coupled to the interposer 1204.

The integrated circuit component 1220 may be a packaged or unpackaged integrated circuit product that includes one or more integrated circuit dies (e.g., the die 902 of FIG. 9, a die comprising the integrated circuit structure 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider or narrower pitch or reroute a connection to a different connection. For example, the interposer 1204 may couple coupling components 1218 having a first pitch to coupling components 1216 having a wider pitch than the first pitch. In the embodiment illustrated in FIG. 12, the integrated circuit component 1220 and the circuit board 1202 are attached to opposing sides of the interposer 1204. In other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias, including but not limited to through hole vias 1210-1 (that extend from a first face 1250 of the interposer 1204 to a second face 1254 of the interposer 1204), blind vias 1210-2 (that extend from the first face 1250 or the second face 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

In some embodiments, certain components of assembly 1200 (e.g., interposer 1204, circuit board 1202, IC components 1220, 1224, 1226, 1232) may include an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin (IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 1204 or circuit board 1202 to the glass layer. The glass layer can comprise through-glass vias (TGVs) that extend through the glass layer to provide electrically conductive paths through the glass core, glass substrate, or glass layer.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 further includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

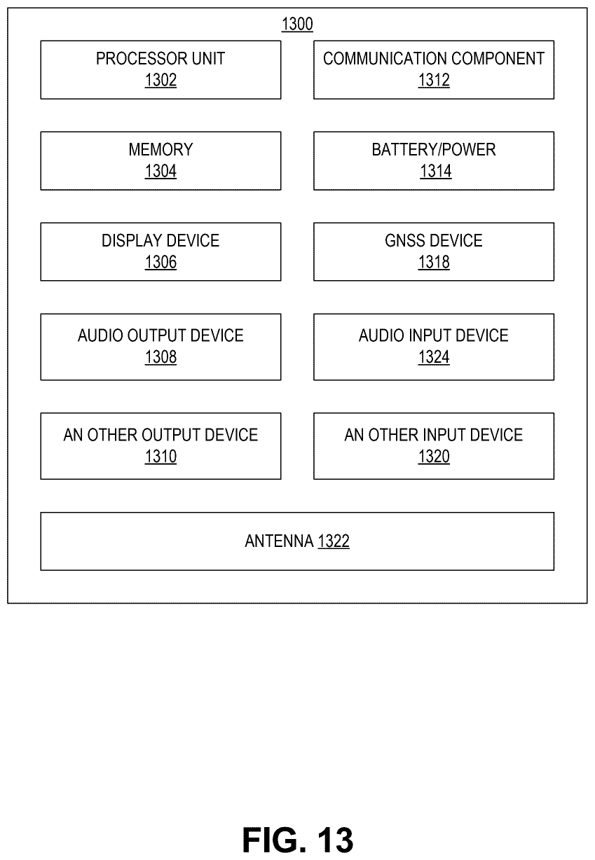

FIG. 13 illustrates a block diagram of an example electrical device 1300 that may include any of the embodiments disclosed herein. For example, any of the components of the electrical device 1300 may include one or more of the strained 2D transistors 100, 300a-d, 400, 600, 800, integrated circuit device assembly 1200, integrated circuit component 1220, integrated circuit structure 1000, or integrated circuit dies 902 disclosed herein, and may be arranged in any of the microelectronic assemblies disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the one or more processor units 1302. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 1300, a first one of the one or more processor units 1302 can be heterogeneous or asymmetric to a second one of the one or more processor units 1302 in the electrical device 1300. There can be a variety of differences between the one or more processor units 1302 in a system in terms of a spectrum of metrics of merit including architectural, microarchitectural, thermal, power consumption characteristics, and the like. These differences can effectively manifest themselves as asymmetry and heterogeneity among the one or more processor units 1302 in the electrical device 1300.

In some embodiments, the electrical device 1300 may include a communication component 1312. For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). In some embodiments, the electrical device 1300 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such as speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System device (GNSS) (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include another output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include another input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a display device (e.g., monitor, television), a set-top box, a video playback device, an entertainment control unit, a stationary gaming console, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the drawings. Additionally, the inclusion of a structural or method feature in a particular drawing is not meant to imply that such feature is required in all embodiments and, in some embodiments, such feature may not be included or may be combined with other features. Further, it should be understood that the various embodiments shown in the drawings are illustrative representations and are not necessarily drawn to scale. In some instances, the same or similar reference numerals may be used to designate the same or similar features in different drawings.

The illustrations and/or descriptions of various embodiments may be simplified, approximated, or idealized for ease of understanding, and as a result, they may not necessarily reflect the level of precision nor variation that may be present in actual embodiments. For example, while some drawings generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

As used herein, references to an “embodiment” or “embodiments” may refer to one or more of the same or different embodiments. Some embodiments may have some, all, or none of the features described for other embodiments.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

As used herein, a list of items joined by the phrase “and/or” can mean any combination of the listed items. For example, the phrase “A, B, and/or C” can mean A; B; C; A and B; A and C; B and C; or A, B and C. As used herein, a list of items referenced by the phrase “at least one of” or the phrase “one or more of” can mean any combination of the listed items. For example, the phrase “at least one of A, B, or C” or the phrase “one or more of A, B, or C” can mean A; B; C; A and B; A and C; B and C; or A, B, and C.

The terms “substantially,” “close,” “approximately,” “near,” “about”, and the like may refer to being within +/−10% of a target value unless otherwise specified. Similarly, terms describing spatial relationships, such as “perpendicular,” “orthogonal,” or “coplanar,” may refer to being substantially within the described spatial relationships (e.g., within +/−10 degrees of orthogonality).

Certain terminology may be used in the foregoing description for the purpose of reference only, and thus is not intended to be limiting. For example, terms such as “upper,” “lower,” “above,” “below,” “bottom,” and “top” may refer to directions in the drawings to which reference is made. Terms such as “front,” “back,” “rear,” and “side” may describe the orientation and/or location of portions of a feature within a consistent but arbitrary frame of reference, which may be made clear by reference to the description and drawings associated with that feature. Such terminology may include the words specifically mentioned above, derivatives thereof, and words of similar import.

As used herein, the phrase “located on” in the context of a first feature located on a second feature refers to the first feature being in direct or indirect physical contact with the second feature (e.g., with or without one or more intervening features between the first and second features).

As used herein, the term “adjacent” refers to features that are arranged next to each other (e.g., side by side, top and bottom) with or without one or more intervening features between them.

As used herein, the terms “coupled” and “connected” may refer to a direct or indirect coupling or connection (e.g., with or without one or more intervening elements).

As used herein, the phrase “electrically coupled” refers to the presence of one or more electrically conductive paths between components that are recited as being electrically coupled.

As used herein, an “integrated circuit” may refer to a packaged or unpackaged integrated circuit product. In one example, a packaged integrated circuit may include one or more integrated circuit dies mounted on a package substrate with the integrated circuit dies and package substrate encapsulated in a casing material, such as a metal, plastic, glass, or ceramic. In one example, a packaged integrated circuit may include one or more processor units mounted on a substrate with an exterior surface of the substrate comprising a solder ball grid array (BGA). In one example of an unpackaged integrated circuit, a single monolithic integrated circuit die may include solder bumps attached to contacts on the die, such that the solder bumps allow the die to be directly attached to a printed circuit board or other substrate. An integrated circuit may include one or more of any computing system component, such as a processor unit (e.g., system-on-a-chip (SoC), processor core, graphics processor unit (GPU), accelerator, chipset processor), input/output (I/O) controller, memory, network interface controller, or any other computing system component described or referenced herein.

The embodiments described herein can be implemented in any integrated circuit (e.g., packaged or unpackaged). In some embodiments, an integrated circuit implemented with the described embodiments may be attached to a printed circuit board. Moreover, in some embodiments, one or more additional components (e.g., other integrated circuits, a battery, an antenna) may also be attached to the printed circuit board. In some embodiments, the printed circuit board and the integrated circuit can be located in a computing device having a housing that encloses the printed circuit board and the integrated circuit.

The described embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine, including volatile or non-volatile memory (e.g., random access memory (RAM), flash memory), hard drives (e.g., hard disk drive (HDD), solid state drive (SSD)), media discs, or combinations thereof.

### Examples

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a semiconductor device, comprising: a source contact and a drain contact, wherein the source contact and the drain contact comprise one or more metals, wherein the one or more metals are stressed; a channel extending between the source contact and the drain contact, wherein the channel comprises a two-dimensional (2D) material, wherein the 2D material is strained; and a gate over the channel.

Example 2 includes the semiconductor device of Example 1, wherein the 2D material comprises a transition metal dichalcogenide.

Example 3 includes the semiconductor device of Example 2, wherein the transition metal dichalcogenide comprises: molybdenum or tungsten; and sulfur, selenium, or tellurium.

Example 4 includes the semiconductor device of Example 2, wherein the transition metal dichalcogenide comprises molybdenum disulfide (MoS₂), tungsten disulfide (WS₂), molybdenum diselenide (MoSe₂), tungsten diselenide (WSe₂), molybdenum ditelluride (MoTe₂), or tungsten ditelluride (WTe₂).

Example 5 includes the semiconductor device of any of Examples 1-4, wherein the one or more metals comprise one or more of gold, nickel, titanium, or tungsten.

Example 6 includes the semiconductor device of any of Examples 1-5, wherein the source contact and the drain contact further comprise: a first layer of metal over the channel; and one or more second layers of metal over the first layer of metal.

Example 7 includes the semiconductor device of Example 6, wherein: the first layer of metal comprises gold; and the one or more second layers of metal comprise one or more of nickel, titanium, or tungsten.

Example 8 includes the semiconductor device of any of Examples 6-7, wherein at least one of the one or more second layers of metal has a thickness in a range of about 50 nanometers to 100 nanometers.

Example 9 includes the semiconductor device of any of Examples 1-8, wherein the source contact and the drain contact have a length in a range of about 200 nanometers to 2 microns.

Example 10 includes the semiconductor device of any of Examples 1-9, wherein the one or more metals induce strain in the 2D material.

Example 11 includes the semiconductor device of any of Examples 1-10, wherein the 2D material is uniaxially tensile strained or uniaxially compressive strained.

Example 12 includes the semiconductor device of any of Examples 1-11, wherein the channel has a length in a range of about 50 nanometers to 2 microns.

Example 13 includes the semiconductor device of any of Examples 1-12, wherein the gate comprises a gate electrode and a gate dielectric, wherein the gate dielectric is between the gate electrode and the channel.

Example 14 includes the semiconductor device of Example 13, wherein the gate is a back gate, wherein the back gate is below the channel, and wherein the source contact and the drain contact are above the channel.

Example 15 includes the semiconductor device of Example 14, wherein: the gate electrode comprises p-doped silicon or n-doped silicon; and the gate dielectric comprises silicon and oxygen.

Example 16 includes the semiconductor device of any of Examples 1-15, further comprising a transistor, wherein the transistor comprises the source contact, the drain contact, the channel, and the gate.

Example 17 includes the semiconductor device of Example 16, wherein the transistor is a planar transistor, a fin field-effect transistor, a ferroelectric field-effect transistor, or a gate-all-around (GAA) transistor.

Example 18 includes an electronic device, comprising: one or more transistors, wherein the respective transistors comprise: a source contact and a drain contact, wherein the source contact and the drain contact comprise a plurality of layers of stressed metal; a channel extending between the source contact and the drain contact, wherein the channel comprises a transition metal dichalcogenide (TMD), wherein the TMD is strained; and a gate over the channel.

Example 19 includes the electronic device of Example 18, wherein the TMD comprises: molybdenum or tungsten; and sulfur, selenium, or tellurium.

Example 20 includes the electronic device of any of Examples 18-19, wherein the plurality of layers of stressed metal include one or more layers of gold, nickel, titanium, or tungsten.

Example 21 includes the electronic device of any of Examples 18-20, wherein the plurality of layers of stressed metal induce strain in the TMD.

Example 22 includes the electronic device of any of Examples 18-21, wherein the one or more transistors include one or more planar transistors, one or more fin field-effect transistors, one or more ferroelectric field-effect transistors, or one or more gate-all-around (GAA) transistors.

Example 23 includes a system, comprising: a circuit board; and an integrated circuit coupled to the circuit board, wherein the integrated circuit comprises a plurality of transistors, wherein the respective transistors comprise: a source contact and a drain contact, wherein the source contact and the drain contact comprise one or more layers of stressed metal; a channel extending between the source contact and the drain contact, wherein the channel comprises a transition metal dichalcogenide (TMD), wherein the TMD is strained; and a gate over the channel.

Example 24 includes the system of Example 23, wherein the transition metal dichalcogenide comprises: molybdenum or tungsten; and sulfur, selenium, or tellurium.

Example 25 includes the system of any of Examples 23-24, wherein the one or more layers of stressed metal comprise one or more of gold, nickel, titanium, or tungsten.

Example 26 includes the system of any of Examples 23-25, wherein the plurality of transistors include one or more planar transistors, one or more fin field-effect transistors, one or more ferroelectric field-effect transistors, or one or more gate-all-around (GAA) transistors.

Example 27 includes the system of any of Examples 23-26, wherein the integrated circuit further comprises processing circuitry, memory circuitry, storage circuitry, or communication circuitry, wherein one or more of the transistors are comprised in the processing circuitry, the memory circuitry, the storage circuitry, or the communication circuitry.

Example 28 includes a semiconductor device, comprising: a source contact and a drain contact, wherein the source contact and the drain contact comprise metal; a channel extending between the source contact and the drain contact, wherein the channel comprises a two-dimensional (2D) material, wherein the 2D material is strained; one or more stressed dielectric layers over the source contact, the drain contact, and the channel; and a gate over the channel.

Example 29 includes the semiconductor device of Example 28, wherein the 2D material comprises a transition metal dichalcogenide.

Example 30 includes the semiconductor device of Example 29, wherein the transition metal dichalcogenide comprises: molybdenum or tungsten; and sulfur, selenium, or tellurium.

Example 31 includes the semiconductor device of Example 29, wherein the transition metal dichalcogenide comprises molybdenum disulfide (MoS₂), tungsten disulfide (WS₂), molybdenum diselenide (MoSe₂), tungsten diselenide (WSe₂), molybdenum ditelluride (MoTe₂), or tungsten ditelluride (WTe₂).

Example 32 includes the semiconductor device of any of Examples 28-31, wherein the one or more stressed dielectric layers comprise one or more stressed insulators.

Example 33 includes the semiconductor device of any of Examples 28-32, wherein the one or more stressed dielectric layers comprise one or more of: silicon and nitrogen; aluminum and oxygen; aluminum and nitrogen; hafnium and oxygen; or zirconium and oxygen.

Example 34 includes the semiconductor device of any of Examples 28-33, wherein the one or more stressed dielectric layers comprise one or more of silicon nitride (SiN), aluminum oxide (AlO), aluminum nitride (AlN), hafnium oxide (HfO), or zirconium oxide (ZrO).

Example 35 includes the semiconductor device of any of Examples 28-34, wherein the one or more stressed dielectric layers include: a first stressed dielectric layer comprising silicon and nitrogen; and a second stressed dielectric layer comprising aluminum and oxygen.

Example 36 includes the semiconductor device of any of Examples 28-35, wherein the one or more stressed dielectric layers have a combined thickness in a range of about 50 nanometers to 100 nanometers.

Example 37 includes the semiconductor device of any of Examples 28-36, wherein the one or more stressed dielectric layers induce strain in the 2D material.

Example 38 includes the semiconductor device of any of Examples 28-37, wherein the 2D material is uniaxially tensile strained or uniaxially compressive strained.

Example 39 includes the semiconductor device of any of Examples 28-38, wherein the channel has a length in a range of about 50 nanometers to 2 microns.

Example 40 includes the semiconductor device of any of Examples 28-39, wherein the gate comprises a gate electrode and a gate dielectric, wherein the gate dielectric is between the gate electrode and the channel.

Example 41 includes the semiconductor device of Example 40, wherein the gate is a back gate, wherein the back gate is below the channel, and wherein the source contact, the drain contact, and the one or more stressed dielectric layers are above the channel.

Example 42 includes the semiconductor device of Example 41, wherein: the gate electrode comprises p-doped silicon or n-doped silicon; and the gate dielectric comprises silicon and oxygen.

Example 43 includes the semiconductor device of any of Examples 28-42, further comprising a transistor, wherein the transistor comprises the source contact, the drain contact, the channel, and the gate.

Example 44 includes the semiconductor device of Example 43, wherein the transistor is a planar transistor, a fin field-effect transistor, a ferroelectric field-effect transistor, or a gate-all-around (GAA) transistor.

Example 45 includes an electronic device comprising a semiconductor device as presented in any of Examples 1-17 and 28-44.

Example 46 includes a system comprising a semiconductor device as presented in any of Examples 1-17 and 28-44.

Example 47 includes a method of forming an apparatus as presented in any preceding example.

Example 48 includes at least one machine-accessible storage medium having instructions stored thereon, wherein the instructions, when executed on a machine, cause the machine to perform a method or realize an apparatus as presented in any preceding example.

1. A semiconductor device, comprising:
a source contact and a drain contact, wherein the source contact and the drain contact comprise one or more metals, wherein the one or more metals are stressed;
a channel extending between the source contact and the drain contact, wherein the channel comprises a two-dimensional (2D) material, wherein the 2D material is strained; and
a gate over the channel.

2. The semiconductor device of claim 1, wherein the 2D material comprises a transition metal dichalcogenide.

3. The semiconductor device of claim 2, wherein the transition metal dichalcogenide comprises:
molybdenum or tungsten; and
sulfur, selenium, or tellurium.

4. The semiconductor device of claim 1, wherein the one or more metals comprise one or more of gold, nickel, titanium, or tungsten.

5. The semiconductor device of claim 1, wherein the source contact and the drain contact further comprise:
a first layer of metal over the channel; and
one or more second layers of metal over the first layer of metal.

6. The semiconductor device of claim 5, wherein:
the first layer of metal comprises gold; and
the one or more second layers of metal comprise one or more of nickel, titanium, or tungsten.

7. The semiconductor device of claim 5, wherein at least one of the one or more second layers of metal has a thickness in a range of about 50 nanometers to 100 nanometers.

8. The semiconductor device of claim 1, wherein the source contact and the drain contact have a length in a range of about 200 nanometers to 2 microns.

9. The semiconductor device of claim 1, wherein the one or more metals induce strain in the 2D material.

10. The semiconductor device of claim 1, wherein the channel has a length in a range of about 50 nanometers to 2 microns.

11. The semiconductor device of claim 1, wherein the gate comprises a gate electrode and a gate dielectric, wherein the gate dielectric is between the gate electrode and the channel.

12. The semiconductor device of claim 11, wherein the gate is a back gate, wherein the back gate is below the channel, and wherein the source contact and the drain contact are above the channel.

13. The semiconductor device of claim 12, wherein:
the gate electrode comprises p-doped silicon or n-doped silicon; and
the gate dielectric comprises silicon and oxygen.

14. The semiconductor device of claim 1, further comprising a transistor, wherein the transistor comprises the source contact, the drain contact, the channel, and the gate.

15. An electronic device, comprising:
one or more transistors, wherein the respective transistors comprise:
a source contact and a drain contact, wherein the source contact and the drain contact comprise a plurality of layers of stressed metal;
a channel extending between the source contact and the drain contact, wherein the channel comprises a transition metal dichalcogenide (TMD), wherein the TMD is strained; and
a gate over the channel.

16. The electronic device of claim 15, wherein the TMD comprises:
molybdenum or tungsten; and
sulfur, selenium, or tellurium.

17. The electronic device of claim 15, wherein the plurality of layers of stressed metal include one or more layers of gold, nickel, titanium, or tungsten.

18. The electronic device of claim 15, wherein the one or more transistors include one or more planar transistors, one or more fin field-effect transistors, one or more ferroelectric field-effect transistors, or one or more gate-all-around (GAA) transistors.

19. A system, comprising:
a circuit board; and
an integrated circuit coupled to the circuit board, wherein the integrated circuit comprises a plurality of transistors, wherein the respective transistors comprise:
a source contact and a drain contact, wherein the source contact and the drain contact comprise one or more layers of stressed metal;
a channel extending between the source contact and the drain contact, wherein the channel comprises a transition metal dichalcogenide (TMD), wherein the TMD is strained; and
a gate over the channel.

20. The system of claim 19, wherein the integrated circuit further comprises processing circuitry, memory circuitry, storage circuitry, or communication circuitry, wherein one or more of the transistors are comprised in the processing circuitry, the memory circuitry, the storage circuitry, or the communication circuitry.
